(19) United States
(12) Patent Application Publication
(10) Pub. No.: US 2002/0031168 A1
(43) Pub. Date: Mar. 14, 2002

(54) Method and apparatus for flexible data rate matching by symbol insertion for a data communication system

(75) Inventors: Min-Goo Kim, Suwon-shi (KR); Jin-Soo Park, Seoul (KR); Young-Hwan Lee, Songnam-shi (KR)

Correspondence Address: Paul J. Farrell, Esq., DILWORTH & BARRESE, LLP, 333 Earle Ovington Blvd., Uniondale, NY, 11553, US

(73) Assignee: SAMSUNG ELECTRONICS CO., LTD, KYUNGKI-DO (KR)

(21) Appl. No.: 09/901,397

(22) Filed: Jul. 9, 2001

(30) Foreign Application Priority Data
Jul. 8, 2000 (KR) 39070/2000
Jul. 8, 2000 (KR) 39157/2000
Jul. 19, 2000 (KR) 42547/2000

(51) Int. Cl. H03B 29/00; H04K 1/00; H04B 15/00; H04L 27/30

(52) U.S. Cl. 375/130; 331/78

(57) ABSTRACT

A flexible data rate matching method and apparatus by symbol repetition in a data communication system. To generate a sequence of N symbols from a sequence of L code symbols less than the N symbols in a system having an encoder for generating the sequence of L code symbols and a channel interleaver for receiving the sequence of N symbols, symbols at generally equidistant (N−L) positions are detected among the L code symbols. The detected symbols are sequentially inserted before or after the detected symbols by repetition.

### PRIORITY

This application claims priority to an application entitled “Method and Apparatus for Flexible Data Rate Matching by Symbol Insertion for Data Communication System” filed in the Korean Industrial Property Office on Jul. 8, 2000 and assigned Ser. No. 2000-39070, to an application entitled “Method and Apparatus for Flexible Data Rate Matching by Symbol Insertion for Data Communication System” filed in the Korean Industrial Property Office on Jul. 8, 2000 and assigned Ser. No. 2000-39157, and to an application entitled “Method and Apparatus for Flexible Data Rate Matching by Symbol Insertion for Data Communication System” filed in the Korean Industrial Property Office on Jul. 19, 2000 and assigned Ser. No. 2000-42547, the contents of each of which are hereby incorporated by reference.

### BACKGROUND OF THE INVENTION

1. Field of the Invention

The present invention relates generally to a data communication system, and in particular, to a method and apparatus for matching frame having a variable number of code symbols according to a variable data rate, to an interleaver size prior to transmission.

2. Description of the Related Art

Convolutional encoding or linear block encoding using a single decoder is a general encoding method in a mobile communication system such as a satellite system, ISDN (Integrated Service Digital Network), a digital cellular system, a W-CDMA (Wide band Code Division Multiple Access) system, UMTS (Universal Mobile Telecommunications System), and IMT (International Mobile Telecommunications)-2000. Code symbols resulting from those channel encoding are generally interleaved by a channel interleaver.

A typical channel interleaver interleaves a frame having as many code symbols as an interleaver size per frame. On the other hand, the more recent channel interleaver performs FDRT (Flexible Data Rate Transmission) interleaving. That is, it interleaves a frame having code symbols different from an interleaver size per frame.

FIG. 1 illustrates a non FDRT-based channel interleaver for interleaving a frame having as many code symbols as an interleaver size. Referring to FIG. 1, if a data rate is fixed, the number L of code symbols per unit frame input to a channel interleaver 100 is always equal to an interleaver size N in a non-FDRT scheme. For example, there are diverse transmission channels including RC1, RC2, RC3, RC4, RC5, RC6, RC7, RC8, and RC9 according to the radio configuration (RC) of an IMT-2000 and they differ in data frame size, code rate, and interleaving. A transmission channel transmits at a predetermined data rate according to its characteristics.

FIG. 2 illustrates an example of a code symbol frame transmitted according to the non-FDRT scheme. Referring to FIG. 2, when the data rate of a physical channel is set at that of RC3, that is, 19.2 kbps, N is 1536. A 20 ms frame at 19.2 kbps contains 384 bits per second and an R=¼ code encoder outputs 1536 bits per second. If a user intends to transmit a frame at 20 kbps, the data rate of the physical channel is set at 38.4 kbps, a minimum data rate higher than 20 kbps by initial negotiation between a base station and a mobile station. Then, N is 3072(=2×1536).

As the data rate increases from 20 kbps to 38.4 kbps, a higher layer writes null data in the remaining area of a channel interleaver (not shown) after input data symbols of 20 kbps×20 msec are filled. In other words, 47.92%(=38.4-20/38.4) of the output of the channel interleaver of size N is transmitted as null data. Consequently, 47.92% energy is dissipated in the aspect of received symbol energy. The energy loss occurs because there is no way to process null data in a physical layer in the non-FDRT scheme. Even if the null data is processed by symbol repetition, symbol combination is not available to a forward supplemental channel (F-SCH). Moreover since null data varies with the data rate of input code symbols, the higher layer should notify the base station and the mobile station of variations beforehand. In reality, energy must be recovered with respect to the null data before channel decoding and an L1/L2 higher layer processes only decoded information symbols after channel decoding. As a result, decoding performance is deteriorated.

FDRT was proposed to improve performance, overcoming the problem of non-FDRT. FDRT is a data rate matching scheme to increase coded data transmission efficiency and improve system performance in a multiple access and multiple channel system using channel encoding. The idea of FDRT is based on the premise that the channel code used is a convolutional code, a linear code, or a concatenated code using a convolutional code. The 3GPP (3rd Generation Project Partnership 2) attracting much interest has settled with FDRT tentatively as the standard of the air interface and FDRT is being realized in real situations.

However, the conventional IS-2000 FDRT and the current IS-2000 FDRT for a convolutional code or a linear block code have the following problems.

(1) The conventional FDRT scheme requires uniform puncturing if possible because it can be supposed that error sensitivity is almost uniform across all code symbols in a frame output from a convolutional encoder or a linear block encoder. The supposition is not valid to the current IS-2000 FDRT.

(2) It was considered in the conventional IS-2000 FDRT that the use of a repetition scheme from the perspective of symbol repetition has little influence on a puncturing pattern. Yet, this symbol repetition must be considered on the level of symbol puncturing. That is, uniform symbol repetition should be achieved on the supposition that error sensitivity is almost uniform across all code symbols in a frame output from an encoder, for FDRT with optimum performance. However, this supposition is not valid to the current IS-2000 FDRT.

(3) Although symbol repetition is enough, symbol puncturing follows the symbol repetition in the conventional IS-2000 FDRT. Therefore, implementation complexity results.

The IS-2000 FDRT for an error correction code such as a turbo code also has the problem described below

As stated before, according to the FDRT for a convolutional code or a linear block code, uniform puncturing is required if possible on the supposition that each frame output from an encoder has almost uniform error sensitivity in all the code symbols. In the case of a turbo code, on the other hand, error sensitivity is different in code symbols of each frame (codeword) output from an encoder. In other words, code symbols from a turbo encoder can be grouped according to their error sensitivities. Also in the case of the turbo code, there is a need for an FDRT scheme that ensures uniform puncturing or repetition for all symbols in each code symbol group. Yet, the current IS-2000 FDRT has limitations in this context.

### SUMMARY OF THE INVENTION

It is, therefore, an object of the present invention to provide a flexible data rate matching method and apparatus, which ensure optimum performance when a convolutional code, a turbo code, and a linear block code are used individually or in combination in a data communication system.

It is another object of the present invention to provide a flexible data rate matching method and apparatus which are simple and flexible at a variable data rate by controlling initial values in a data communication system using a convolutional code, a turbo code, or a linear block code.

It is a further object of the present invention to provide a flexible data rate matching method and apparatus for a data communication system

The foregoing and other objects of the present invention can be achieved by providing a flexible data rate matching method and apparatus by symbol repetition in a data communication system. To generate a sequence of N symbols from a sequence of L code symbols less than the N symbols in a system having an encoder for generating the sequence of L code symbols and a channel interleaver for receiving the sequence of N symbols, symbols at generally equidistant (N−L) positions are detected among the L code symbols and the detected symbols are sequentially inserted before or after the detected symbols by repetition.

### BRIEF DESCRIPTION OF THE DRAWINGS

The above and other objects, features and advantages of the present invention will become more apparent from the following detailed description when taken in conjunction with the accompanying drawings in which:

FIG. 1 illustrates a typical non-FDRT-based channel interleaver;

FIG. 2 illustrates an example of a code symbol frame transmitted according to non-FDRT;

FIG. 3 is a block diagram of an FDRT device that performs symbol repetition & puncturing according to the IS-2000 specifications;

FIG. 4 is a block diagram of a transmitting device in an FDRT scheme according to an embodiment of the present invention;

FIGS. 5A, 5B, and 5C illustrate examples of symbol outputs from an FDRT device shown in FIG. 4;

FIG. 6 is a flowchart illustrating an FDRT operation according to the embodiment of the present invention;

FIG. 7 is a detailed block diagram of the FDRT device according to the embodiment of the present invention;

FIG. 8 is a block diagram of an FDRT device according to another embodiment of the present invention;

FIG. 9 is a view for describing a problem possibly encountered in FDRT-processing code symbols output as one sequence from a turbo encoder;

FIG. 10 illustrates examples of symbols generated with an initial offset concept introduced according to a third embodiment of the present invention;

FIG. 11 is a flowchart illustrating an initial offset determination procedure for determining the first symbol to be repeated in a frame after encoding in an encoder that outputs code symbols in a sequence according to the third embodiment of the present invention; and

FIG. 12 is another flowchart illustrating an initial offset determination procedure for determining the first symbol to be repeated in a frame after encoding in an encoder that outputs code symbols in a sequence according to the third embodiment of the present invention.

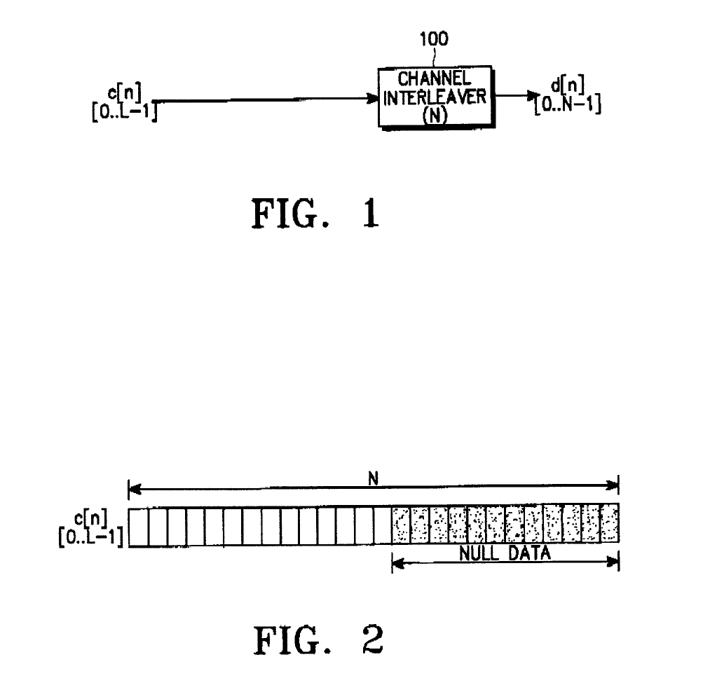

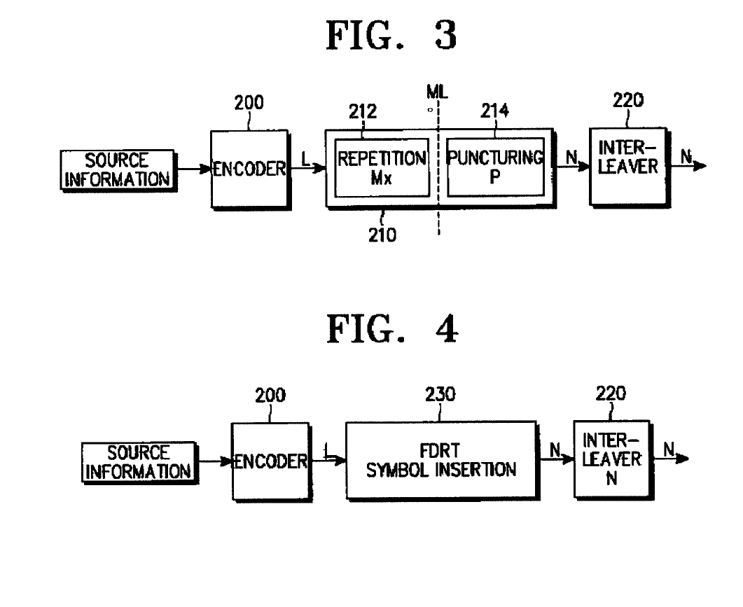

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

Before a detailed description of the present invention, an FDRT scheme performing symbol repetition & puncturing as provided by the IS-2000 specifications will be described below.

Referring to FIG. 3, since during the input of L code symbols from an encoder 200, an FDRT block 210 outputs N code symbols equal to or greater than the L code symbols, the input symbols are subject to symbol repetition. Therefore, a symbol puncturer 214 is used to match the repeated code symbols to the number of output symbols, the size N, of an interleaver 220. According to the above FDRT scheme, code symbols are repeated M times in a repeater 212 and the repeated code symbols are punctured in the symbol puncturer 214 to match the code symbols to the interleaver size N.

Embodiment 1

A novel FDRT scheme according to an embodiment of the present invention inserts (N−L) symbols among L symbols and outputs N symbols finally, as compared to the conventional IS-2000 FDRT scheme where symbol puncturing is performed to delete (LM−N) symbols from LM symbols after M symbol repetitions. A transmitting device according to the novel FDRT scheme is illustrated in FIG. 4.

Referring to FIG. 4, an encoder 200 outputs a code sequence having L code symbols by encoding source information. An FDRT device 230 inserts (N−L) symbols among the L code symbols and outputs N symbols. Specifically, the FDRT device 230 detects generally equidistant (N−L) symbol positions among the L code symbols and sequentially inserts the (N−L) symbols before or after the code symbols at the detected positions. An interleaver 220 interleaves the N symbols received from the FDRT device 230. As shown in FIG. 4, the FDRT scheme according to the embodiment of the present invention is very simple because M times symbol repetition as illustrated in FIG. 3 is omitted.

Now, an algorithm run in the FDRT device 230 will be described in detail. According to the FDRT algorithm according to the embodiment of the present invention, (N−L) code symbols are inserted among L code symbols without symbol repetition accompanied by puncturing. For example, if a data rate is 17 kbps, a frame is 20 msec in duration, a code rate R is ¼, and the data rate of a channel to be transmitted is 19.2 kbps, the FDRT device 230 inserts [(19.2−17)×20×4] symbols among the L symbols. Since optimum FDRT is characterized by almost uniform error sensitivity across all symbols in one frame (codeword) output from an encoder, the FDRT device 230 must perform uniform symbol insertion in one frame if possible. Once the interleaver size N and the number L of input code symbols are given, the number of inserted symbols is calculated. After parameters, listed in Table 1, required for the FDRT algorithm are determined, a symbol insertion pattern (or a symbol repetition pattern) will be determined. It is to be noted here that symbol insertion and symbol repetition are used in the same meaning.

TABLE 1

| Parameters | Definition |
|---|---|
| Nis = N − L | Number of inserted symbols (because N ≧ L, Nis is always |
| | a positive number) |
| L | Number of code symbols input to FDRT block |
| N | Number of symbols output from FDRT block |
| Eacc | Error accumulation value |
| (Ia, Ib) | Variable determining first repeated symbol position in |
| | frame (Ib is an integer satisfying 1 ≦ Ib ≦ Ia) |

In Table 1, L is the number of code symbols input to the FDRT device 230 after encoding in the encoder 200 and N is the size of the interleaver 220, the number of code symbols output from the FDRT device 230 after data rate matching. Nis is the number of inserted symbols in the FDRT device 230. Eacc is a value obtained by sequentially decreasing a predetermined initial value by a predetermined decrement. In the embodiment of the present invention, Eacc is generated for each symbol in a frame and compared with 0. If Eacc is less than or equal to 0, the symbol is repeated. In this sense Eacc is called an error accumulation value and the initial value is called an initial error accumulation value. The initial value can be (Ia×Nis).

TABLE 2
Eacc=Ib*L
M=1
do while mL

Eacc=Eacc-Ia*Nis;
do while Eacc≦0

repeat mth symbol
Eacc=Eacc+Ia*L

end do
m=m+1

end do

Table 2 is the FDRT algorithm according to the embodiment of the present invention. “repeat mth symbol” means that an mth symbol is repeated.

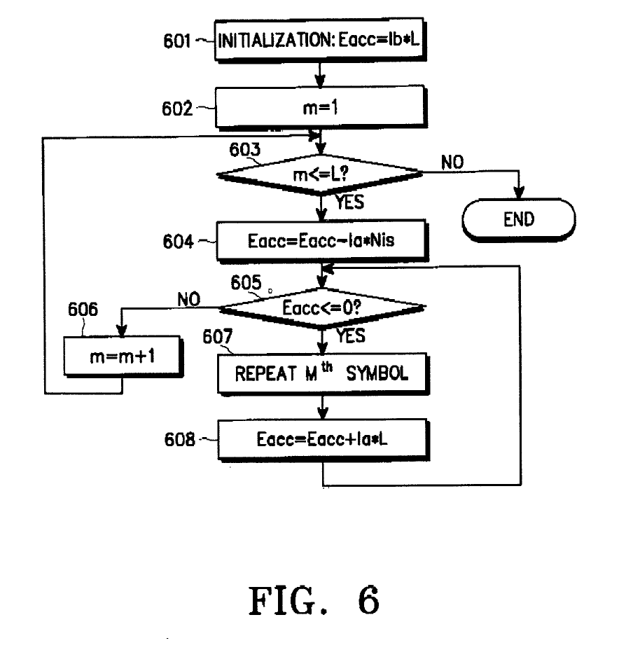

If Eacc≦0, the mth symbol repetition continues in a “do while” loop until Eacc >0. When the algorithm is completely run, that is, when the “while” loop is performed until m=L, a total of N symbols are generated. The N symbols are output from the FDRT device 230 by inserting (N−L) symbols among L input code symbols. The FDRT algorithm of Table 2 will be described in more detail later referring to FIG. 6.

Meanwhile, the algorithm of Table 2 is also applicable to VDRT (Variable Data Rate Transmission) using an arbitrary value M (repeating times). Since the FDRT algorithm selects repeated symbol positions, consecutive puncturing that discards particular code symbols does not occur unlike the conventional FDRT scheme performing symbol repetition & puncturing. Accordingly, the performance deterioration caused by the consecutive puncturing does not occur either.

If Eacc, 0, Ia*Nis, and Ia*L are defined as an error accumulation value, a threshold, a decrement, and an increment, respectively, the algorithm is performed in the following steps of (a) setting Eacc for the first symbols among L code symbols; (b) comparing Eacc with 0; (c) updating Eacc by Eacc+Ia*L if Eacc is less than 0 and returning to step (b); (d) updating Eacc by Eacc−Ia*Nis if Eacc is greater than 0 and returning to step (b); and (e) ending the procedure if a sequence of N symbols is generated from the L code symbols during steps (c) or (d). While it is preferable to set the threshold, the decrement, and the increment to 0, Ia*Nis, and Ia*L respectively, they can be set to appropriate empirical values.

Application cases of the FDRT algorithm according to the embodiment of the present invention will be presented below In Case 1, M=1, that is, no symbol repetition is given. In Case 2, M=2. A code sequence is repeated once and thus two same code sequences are generated. In Case 3, M=3. A code sequence is repeated twice and three same code sequences are generated. In all cases, (Ia, Ib)=(2, 1)

(Case 1)

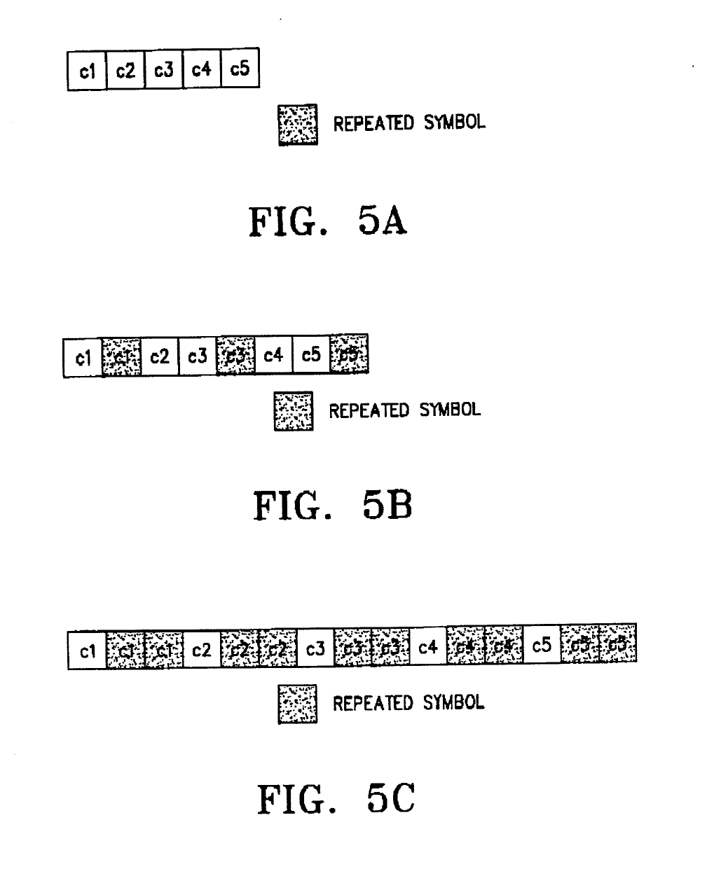

If L=5 and N=5, Nis=N−L=5−5=0. This case requires no symbol repetition. Table 3 shows the case where a symbol repetition pattern is given as c1, c2, c3, c4, c5 for code symbol positions m=1, 2, 3, 4, 5, that is, there is no symbol repetition. Therefore, N(=5) input code symbols are simply output according to the symbol repetition pattern as shown in FIG. 5A.

TABLE 3

| | Positions of input symbols | | | | |
|---|---|---|---|---|---|
| | m = 1 | m = 2 | m = 3 | m = 4 | m = 5 |
| Eacc = Eacc − Ia*Nis | +5 | +5 | +5 | +5 | +5 |
| (Eacc = 5) | | | | | |
| Eacc = Eacc + Ia*L | NA | NA | NA | NA | NA |
| Repetition | No | No | No | No | No |
| Symbol repetition | c1 | c2 | c3 | c4 | c5 |
| pattern | | | | | |

For example, the initial error accumulation value Eacc is 5 and an error accumulation value Eacc for an input symbol at position m=1 is 5−2×(N−L)=5−2×0=5 in Table 3. Because the error accumulation value Eacc is greater than 0, the symbol at m=1 is not repeated. A symbol repetition pattern for the input symbol c1 at m=1 is determined as c1 and the input symbol is simply output. NA in Table 3 represents “Not Available” in the meaning that the error accumulation value calculation by Eacc=Eacc+Ia*L is not required.

(Case 2)

If L=5 and N=8, Nis=N−L=8−5=3. Three code symbols must be inserted among five input code symbols. Table 4 shows the case where a symbol repetition pattern is given as c1, c1, c2, c3, c3, c4, c5, c5 for code symbols at m=1, 2, 3, 4, 5. According to the symbol repetition pattern of c1, c1, c2, c3, c3, c4, c5, c5, the input code symbols are repeated and N (=8) code symbols are output as shown in FIG. 5B.

TABLE 4

| | Positions of input symbols | | | | |
|---|---|---|---|---|---|
| | | m = | | m = | |
| | m = 1 | 2 | m = 3 | 4 | m = 5 |
| Eacc = Eacc − Ia*Nis | −1 | 3 | −3 | 1 | −5 |
| (Eacc = 5) | | | | | |
| Eacc = Eacc + Ia*L | 9 | 3 | 7 | 1 | 5 |
| Repetition | Repetition | No | Repetition | No | Repetition |
| Symbol repetition | c1, c1 | c2 | c3, c3 | c4 | c5, c5 |
| pattern | | | | | |

For example, the initial error accumulation value Eacc is 5 and an error accumulation value Eacc for an input symbol at position m=1 is 5−2×(N−L)=5−2×3=−1 in Table 4. Because the error accumulation value Eacc is less than 0, the symbol at m=1 is repeated. Thus Eacc is updated to Eacc+Ia*L(−1+2×3=5). The updated error accumulation value Eacc is greater than 0 and so the symbol at m=1 is not repeated any more. A symbol repetition pattern for the input symbol c1 at m=1 is determined as c1, c1 and two output symbols are generated for the input symbol.

(Case 3)

If L=5 and N=15, Nis=N−L=15−5=10. Ten code symbols must be inserted among five input code symbols. Table 5 shows the case where a symbol repetition pattern is given as c1, c1, c1, c2, c2, c2, c3, c3, c3, c4, c4, c4, c5, c5, c5 for code symbols at m=1, 2, 3, 4, 5. According to the symbol repetition pattern of c1, c1, c1, c2, c2, c2, c3, c3, c3, c4, c4, c4, c5, c5, c5, the input code symbols are repeated and N (=15) code symbols are output as shown in FIG. 5C.

TABLE 5

| | Positions of input symbols | | | | |
|---|---|---|---|---|---|
| | m = 1 | m = 2 | m = 3 | m = 4 | m = 5 |
| Eacc = Eacc − Ia*Nis | −15 | −15 | −15 | −15 | −15 |
| (Eacc = 5) | | | | | |
| Eacc = Eacc + Ia*L | −5, +5 | −5, +5 | −5, +5 | −5, +5 | −5, +5 |
| Repetition | Repetition | Repetition | Repetition | Repetition | Repetition |
| Symbol repetition | c1, c1, c1 | c2, c2, c2 | c3, c3, c3 | c4, c4, c4 | c5, c5, c5 |
| pattern | | | | | |

In Table 5, −5, +5 are Eacc generated during a nested while loop according to the condition “do while Eacc≦0”. Therefore, as the nested while loop is run, symbol repeating times increase. For example, the initial error accumulation value Eacc is 5 and an error accumulation value Eacc for an input symbol at the position m=1 is 5−2×(N−L)=5−2×10=−15 in Table 5. Because the error accumulation value Eacc is less than 0, the symbol at m=1 is repeated. As repetition continues, Eacc is updated to Eacc+Ia*L(−15+2×5=−5). The updated error accumulation value Eacc is less than 0 and so the symbol at m=1 is repeated once more. Then, Eacc is updated again to Eacc+Ia*L(−5+2×5=5). Since the updated error accumulation value Eacc is greater than 0, the symbol at m=1 is not repeated any more. Consequently, the symbol at m=1 is repeated twice. A symbol repetition pattern for the input symbol c1 at m=1 is determined as c1, c1, c1 and three output symbols are generated for the input symbol.

In the above cases, it is assumed that the parameter (Ia, Ib) is (2, 1). This parameter (Ia, Ib) can be set to a different value according to the characteristic of an error correction code used. For example, the error correction code can be a convolutional code, a linear block code, or a turbo code. Then, the parameter (Ia, Ib) can be set to (2, 1), (4, 1), (8, 1), (L, 1), or (L, K) (K is an integer satisfying 1≦K≦L). Therefore, it is to be appreciated that the parameter (Ia, Ib) is set to a value that ensures optimum performance according to the error correction code used, in consideration of its characteristic described below in the present invention. The following equation indicates the first repeated symbol position, Initial Offset_m among code symbols in one frame.

Initial Offset_{—}m=[Ib*L/Ia*Nisl]=[(Ib/Ia)*(L/Nis)] (1)

Referring to Eq. 1, the position of the first symbol to be repeated in one frame can be adjusted within the range of (L/Nis) by controlling the parameter (Ia, Ib).

If Ib is a constant, Initial Offset_m decreases as Ia increases. Thus the first repeated symbol position moves toward the start of the frame. If Ia≧(Ib*Nis/L), Initial Offset_m is 1. Hence, the first symbol in the frame is always repeated. Since Ib controls Initial Offset_m with Ia, Ib is set to a value in the range of 1≦Ib≦Ia after Ia is determined. If Ia is a constant, Initial Offset_m increases as Ib increases and vice versa. Therefore, the first repeated symbol position is adjusted by controlling Ib. That is, Ia is a parameter that determines a symbol repetition period and the first repeated symbol and Ib is a parameter that determines the first repeated symbols and the whole repeated symbol positions. As noted from the algorithm, Ib influences only the setting of an initial Eacc value, and Ia influences the symbol repetition period since the increment or decrement include Ia according to whether repetition is performed or not. Thus, Ib determines the whole repeated symbol positions.

Table 6 shows Initial Offset_m for the above three cases.

TABLE 6

| | Cases | | |
|---|---|---|---|
| | Case 1 | Case 2 | Case 3 |
| M | 1.0 | 1.6 (=8/5) | 3.0(=15/5) |
| Initial Offset_m | ┌ {(½) * (5/0)} ┐ = ∞ | ┌ {(½) * (5/3)} ┐ = ┌⅚┐ | ┌ {(½) * (5/3)} ┐ = ┌⅚┐ |
| | | = 1 | = 1 |
| Repetition | NA | 1^{st} symbol (m = 1) | 1^{st} symbol (m = 1) |

According to Table 6, Case 1 needs no repetition and since Initial Offset_m is 1 for both Case 2 and Case 3, the first symbol is the initial repetition position.

FIG. 6 is a flowchart illustrating the FDRT algorithm according to the embodiment of the present invention. It is assumed that L, N, and (Ia, Ib) are given before the FDRT algorithm is run.

Referring to FIG. 6, an initialization is performed by receiving Eacc (=Ib*L) in step 601. Eacc is generated by sequentially reducing a predetermined initial error accumulation value by a predetermined decrement as stated before. In step 602, code symbol position m is set to 1. It is determined whether m is less than or equal to L in step 603. If m is less than or equal to L, Eacc is updated by Eacc−(Ia*Nis) in step 604.

In step 605, it is determined whether the updated Eacc is less than or equal to 0. If the updated Eacc is greater than 0, m is increased by 1 in step 606 to perform an operation of designating the next position as a symbol repetition position in steps 603, 604, and 605. The procedure of comparing the updated Eacc with 0 and increasing m is repeatedly performed for all the code symbols in one frame. Therefore, steps 603, 604, and 605 are repeated until m≦L.

If the updated Eacc is less than or equal to 0 in step 605, the mth symbol is repeated in step 607. In step 608, Eacc is updated by Eacc+(Ia*L). Then, the procedure returns to step 605.

Steps 603 to 606 are performed to obtain Eacc for each code symbol in the frame and determine repeated symbols according to Eacc. Steps 607 and 608 are performed to determine how many times to repeat the symbols and repeat them. In accordance with the embodiment of the present invention, Nis(=N−L) symbol positions are detected among L code symbols and Nis symbols at the determined positions are sequentially repeated, thereby generating a sequence of N symbols. Here, the (N−L) symbols are equidistant among the L symbols.

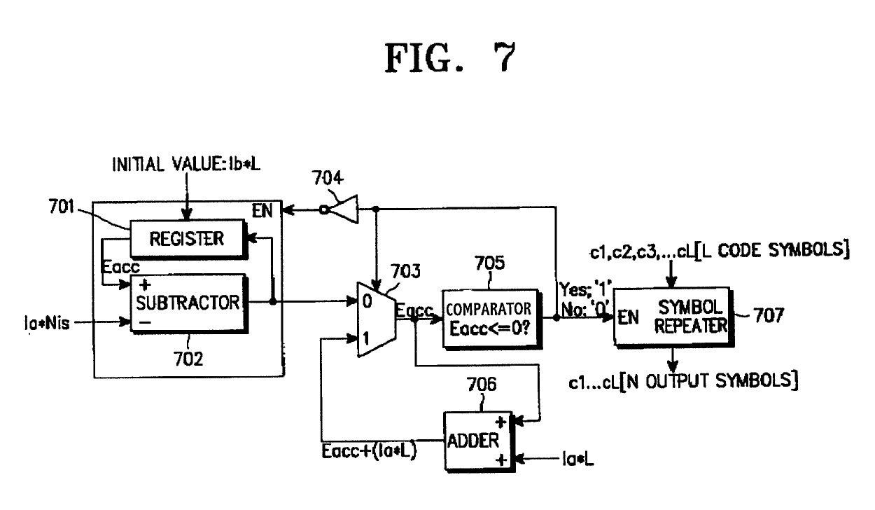

FIG. 7 is a detailed block diagram of the FDRT device for performing the procedure shown in FIG. 6 according to the embodiment of the present invention. In FIG. 7, EN represents an enable signal. If EN=1, a corresponding block is enabled and if EN=0, the block is disabled. A symbol repeater 707 simply outputs a code symbol ck received at every clock pulse when EN=0 and repeats the code symbol ck when EN=1. The enable signal EN=1 can occur repeatedly for one code symbol. An enable signal EN for the symbol repeater 707 is output from a comparator 705 for determining whether Eacc≦0. If Eacc≦0, the comparator 705 outputs EN=1 and if Eacc>0, it outputs EN=0. The enable signal EN output from the comparator 705 is also fed to a register 701 and a subtractor 702 via a selector 703 and an inverter 704 to enable the register 701 and the subtractor 702.

As shown in FIG. 7, the FDRT device according to the embodiment of the present invention is comprised of the register 701, the subtractor 702, the selector 703, the inverter 704, the comparator 705, an adder 706, and the symbol repeater 707. The register 701 downloads a value (Ib*L) as an initial error accumulation value Eacc and stores it when the FDRT device is initially operated and then stores Eacc received from the subtractor 702. The subtractor 702 subtracts (Ia*Nis) from Eacc stored in the register 701 and outputs the subtraction result as updated Eacc. The operation of the register 701 for the initialization corresponds to step 601 of FIG. 6 and the operation of the subtractor 702 corresponds to step 604. Only when the output signal of the inverter 704 is 1, that is, the output signal of the comparator 705 is 0, the subtractor 702 outputs Eacc.

The selector 703, which can be a multiplexer (MUX), initially feeds Eacc received from the subtractor 702 to both the comparator 705 and the adder 706 and then selectively outputs the values received from the subtractor 702 and the adder 706 to both the comparator 705 and the adder 706 according to the level of the enable signal EN received from the comparator 705. If EN=0, the selector 703 outputs Eacc received from the subtractor 702 to the comparator 705 and the adder 706. If EN=1, the selector 703 outputs the value received from the adder 706 to the comparator 705 and the adder 706.

The comparator 705 compares Eacc received from the selector 703 with 0, determines whether Eacc received from the selector 703 is less than or equal to 0 and outputs a decision result signal. If Eacc is less than or equal to 0, the comparator 705 outputs EN=1 and if Eacc is greater than 0, the comparator 705 outputs EN=0. According to the enable signal EN received from the comparator 705, the symbol repeater 707 outputs an input code symbol simply without repetition or repeats the code symbol. The operations of the selector 703, the register 701, and the subtractor 702 are controlled by the enable signal EN of the comparator 705. The operation of the comparator 705 corresponds to step 605 of FIG. 6.

The adder 706 adds Eacc received from the selector 703 to (Ia*L) and feeds the sum to the selector 703. When EN=1, the sum is selected by the selector 703. This operation corresponds to step 608 of FIG. 6.

If Eacc output from the register 701 is a first error accumulation value, Eacc output from the subtractor 702 is a second error accumulation value, Eacc output from the adder 706 is a third error accumulation value, Eacc output from the selector 703 is a fourth error accumulation value, and Ia and Ib used to determine the first repeated symbol in a frame are a first variable and a second variable (Ib is an integer satisfying 1≦Ib≦Ia) respectively, the register 701 outputs a first parameter obtained by multiplying the second parameter by L as the first error accumulation value for the first symbol and outputs the second error accumulation value of the previous symbols as updated first error accumulation values for the following symbols. The register 701 performs the update operation in response to a control signal generated when the comparator 705 determines that the fourth error accumulation value is greater than a predetermined threshold (e.g., 0). The subtractor 702 subtracts a second parameter being the product of the first variable and Nis(=N−L) from the first error accumulation value and outputs the subtraction result as the second error accumulation value. The selector 703 selectively outputs the second or third error accumulation value as the fourth error accumulation value under the control of the comparator 705. The adder 706 adds the fourth error accumulation value to a third parameter being the product of the first variable and L, and outputs the sum as the third error accumulation value. The comparator 705 compares the fourth error accumulation value with the predetermined threshold. If the fourth error accumulation value is greater than the threshold, the comparator 705 outputs a control signal to control the selector 703 to select the second error accumulation value as the fourth error accumulation value. If the fourth error accumulation value is less than or equal to the threshold, the comparator 705 outputs a control signal to control the selector 703 to select the third error accumulation value as the fourth error accumulation value. The inverter 704 is connected between the comparator 705 and the register 701, and enables the register 701 in response to the control signal from the comparator 705 so that the register 701 updates the first error accumulation value to the second error accumulation value. The symbol repeater 707 receives a decision result from the comparator 705 and inserts symbols for which the error accumulation values are less than or equal to the threshold by repetition, to thereby generate a sequence of N symbols.

Embodiment 2

The FDRT scheme according to the first embodiment of the present invention enables uniform puncturing or uniform repetition (insertion) in consideration of the characteristic that convolutional coded symbols or linear block coded symbols show almost the same error sensitivity in one frame or one codeword. This FDRT scheme is also applicable to turbo codes by setting appropriate parameters, which will be described herein below

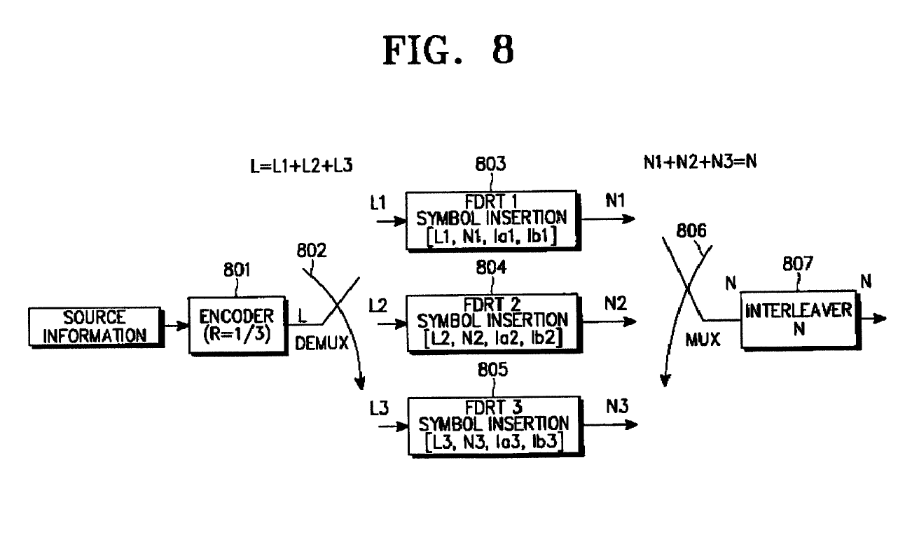

FIG. 8 is a block diagram of an FDRT device according to another embodiment of the present invention. A R=⅓ turbo encoder is used in the FDRT device.

Referring to FIG. 8, an encoder 801 encodes source information and outputs a sequence of L code symbols. A demultiplexer (DEMUX) 802 separates the L code symbols into an X group with L1 information symbols, a Y group with L2 parity symbols, and a Z group with L3 parity symbols. Here, L=L1+L2+L3 and L1, L2, and L3 can be identical or different. For the input of the L1 information symbols, a first FDRT block 803 outputs N1 symbols by inserting (N1-L1) symbols among the L1 code symbols. The first FDRT block 803 determines generally equidistant (N1-L1) symbol positions and sequentially repeats the (N1-L1) symbols at the determined positions. For the input of the L2 information symbols, a second FDRT block 804 outputs N2 symbols by inserting (N2-L2) symbols among the L2 code symbols. The second FDRT block 804 determines generally equidistant (N2-L2) symbol positions and sequentially repeats the (N2-L2) symbols at the determined positions. For the input of the L3 information symbols, a third FDRT block 805 outputs N3 symbols by inserting (N3-L3) symbols among the L3 code symbols. The third FDRT block 805 determines generally equidistant (N3-L3) symbol positions and sequentially repeats the (N3-L3) symbols at the determined positions. A MUX 806 multiplexes the N1 symbols, N2 symbols, and N3 symbols received from the FDRT blocks 803, 804, and 805 and outputs N symbols. Here, N1+N2+N3=N and N1, N2, and N3 can be identical or different. An interleaver 807 interleaves the N symbols received from the MUX 806 and outputs N interleaved symbols.

As noted from FIG. 8, code symbols output from the R=⅓ turbo encoder 802 are separated into the X group (L1) with information symbols, the Y group (L2) with parity symbols, and the Z group (L3) with parity symbols and the groups are FDRT-processed separately. The FDRT algorithm described above is also applied to the FDRT blocks 803, 804, and 805 only if parameters (Li, Ni) and (Iai, Ibi) are determined for each FDRT block. As stated above, L=L1+L2+L3 and N=N1+N2+N3. Therefore, the important issue to improving the performance of a turbo code is how the (N−L) inserted symbols are distributed to the groups. The optimum turbo code performance can be achieved by determining a different number of inserted symbols for each group according to the error sensitivity of the group, controlling the above parameters. For example, if the information symbol group X is relatively significant, the number of repeated symbols is increased for the X group (e.g., L/2) and the remaining available repeated symbol number is divided into equal halves for the Y and Z groups (e.g., L/4 for each). Since the determination of the number of repeated symbols is related with a code rate and a generator polynomial, it is necessary to optimize parameters required to achieve an optimum data rate and an optimum generator polynomial. The optimization of the parameters will not be described herein but empirical optimum values can be used as the parameters. Once Li, Ni, Iai, and Ibi are determined for each group, each FDRT block performs symbol insertion (i.e. symbol repetition) in the same manner as described before.

Embodiment 3

The third embodiment of the present invention is provided to optimize the performance of a turbo code even when the X, Y, and Z groups are output as one code sequence like a convolutional code or a linear block code. That is, uniform symbol insertion or repetition is performed on code symbols in a frame output from a turbo encoder in the same manner as for a convolutional code. In addition, an initial offset is controlled to satisfy the following condition in consideration of the characteristic of a turbo code and thus to achieve performance approximate to the performance in the second embodiment.

(Condition) A turbo code is used and repetition of the X group is reinforced if possible to ensure the optimum performance of the turbo code in an encoder that outputs code symbols as a sequence.

To meet the above condition, the third embodiment of the present invention provides an offset control method.

In a communication system where the number of output code symbols of a R=⅓ turbo code encoder is greater than the size of an interleaver connected after the turbo encoder, the code symbols are typically repeated and then punctured in order to match the code symbols to the interleaver size. If a symbol puncturing period is a multiple of 3 and puncturing starts with the first code symbol, this implies that only information symbols are successively punctured. For example, if L=15 and N=20, the code symbols are repeated M times (=2) and the number of punctured symbols P=LM−N=10. Therefore, an average puncturing period is 3. The performance of the turbo code in this case is deteriorated as compared to puncturing parity symbols. The problem is also observed in the FDRT scheme where code symbols are repeatedly inserted for data rate matching.

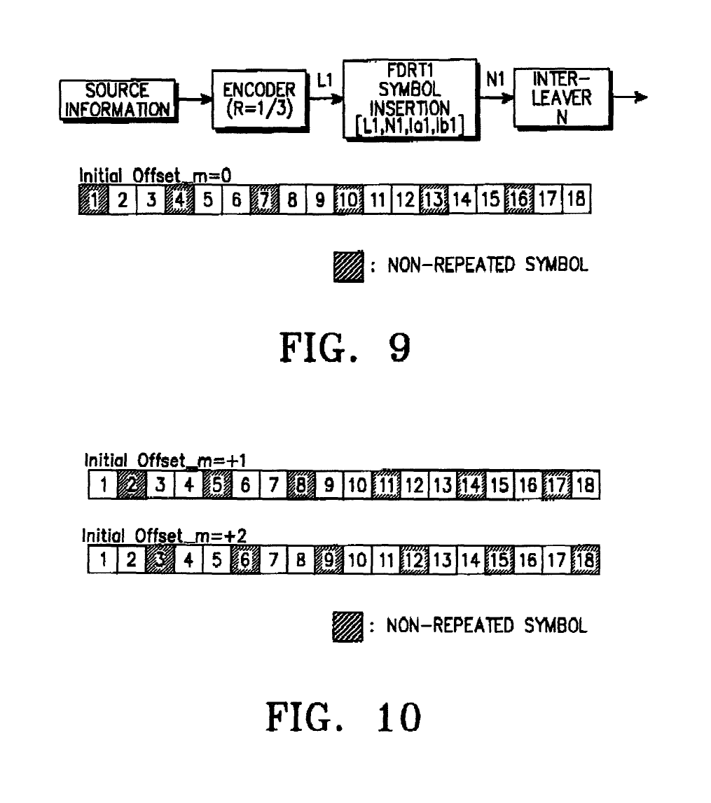

FIG. 9 is a view referred to for describing the problem possibly generated when a sequence of turbo encoded symbols is subject to FDRT processing. Referring to FIG. 9, if a R=⅓ turbo encoder is used, the turbo encoder sequentially generates information symbols 1, 4, 7, 10, 13, 16 of an X group, parity symbols 2, 5, 8, 11, 14, 17 of a Y group, and parity symbols 3, 6, 9, 12, 15, 18 of a Z group. Unless the marked information symbols are repeated, the information code symbols will have small symbol energy relative to the parity symbols. As a result, the performance of a turbo code is deteriorated. This problem can be solved by controlling non-repeated symbol positions by introducing an initial offset concept expressed as Eq. 1 and thus allowing the parity symbols to be periodically non-repeated.

FIG. 10 illustrates examples of symbols generated when the initial offset concept is applied to FDRT processing of a sequence of turbo encoded symbols according to a third embodiment of the present invention. It can be noted from FIG. 10 that the information symbols 1, 4, 7, 10, 13, 16 are repeated whereas the parity symbols 2, 5, 8, 11, 14, 17 or 3, 6, 9, 12, 15, 18 are not repeated.

TABLE 7

| Code rate | R = 1/2 | R = 1/3 | R = 1/4 | R = 1/5 |
|---|---|---|---|---|
| Distance D between | 2m, m = 1, 2, 3, . . . | 3m, m = 1, 2, 3, . . . | 4m, m = 1, 2, 3, . . . | 5m, m = 1, 2, |
| non-repeated | | | | 3, . . . |
| symbols | | | | |
| Offset control value | +1 symbol | +1, +2 symbols | +1, +2, +3 | +1, +2, +3, +4 |
| | | | symbols | symbols |

Table 7 lists offset control values according to data rates to solve the problem involved in repeating no information symbols among code symbols output from a turbo encoder. This problem is also observed when the information symbols are punctured, but the following description is limited to the former case. A problem arises when D is 2 or a multiple of 2 for R=½, when D is 3 or a multiple of 3 for R=⅓, and when D is 4 or a multiple of 4 for R=¼. “Offset control value” in Table 7 is an offset value given to solve the aforementioned problem. For example, if R=⅓, a symbol offset of +1 is assigned to make the parity symbols 2, 5, 8, 11, 14, 17 of the Y group periodically non-repeated. Similarly, a symbol offset of +2 makes the parity symbols 3, 6, 9, 12, 15, 18 of the Z group periodically non-repeated. The offset control can be implemented in many ways. Therefore, the offset control described herein is a mere example. The offset control solves the problem of successive non-repetition of information symbols that are most significant in a turbo code and improves performance.

Use of the parameter (Ia, Ib) will be described as one way of offset control. The first repeated symbol position in a frame, Initial Offset_m is determined by Eq. 1, as stated before. According to Eq. 1, the parameter (Ia, Ib) controls a repetition period (L/Nis) by (Ib/Ia). Thus, if D is 2m, 3m, or 4m (m=1, 2, 3, . . .) according to data rates, the initial offset (Initial Offset_m) can be determined to set a desired symbol repetition position by use of (Ib/Ia). That is, the initial offset m can be determined by setting (Ib/Ia)=(Nis/L)*1, (Ib/Ia)=(Nis/L)*2, (Ib/Ia)=(Nis/L)*3, and (Ib/Ia)=(Nis/L)*4 to determine offset control values as shown in Table 7 according to data rates of a turbo code and by appropriately selecting an (Ib/Ia) value in consideration of L and N.

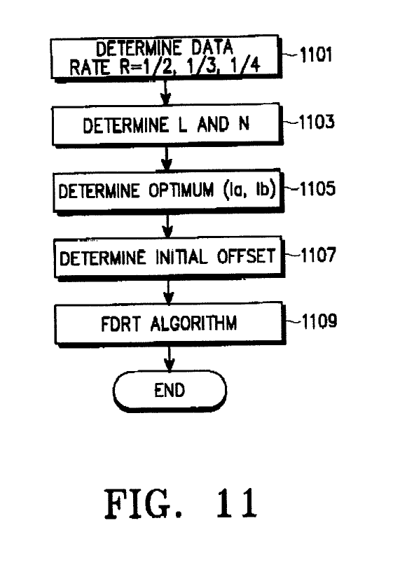

FIG. 11 is a flowchart illustrating an initial offset determining operation to determine the first repeated symbol position in a frame after encoding in an encoder that outputs code symbols in a sequence according to the third embodiment of the present invention. Referring to FIG. 11, a code rate is determined in step 1101. The code rate can be 1/2, 1/3, or ¼. In step 1103, the size of an input frame, L and the size of an output frame, N are determined. L is the number of symbols input to an FDRT block or output from an encoder and N is the number of symbols output from the FDRT block. L and N are provided by a higher layer. An optimum (Ia, Ib) is determined by Eq. 1 in step 1105, an initial offset is obtained from the parameter (Ia, Ib) in step 1107, and the above-described FDRT algorithm of the present invention is performed in step 1109.

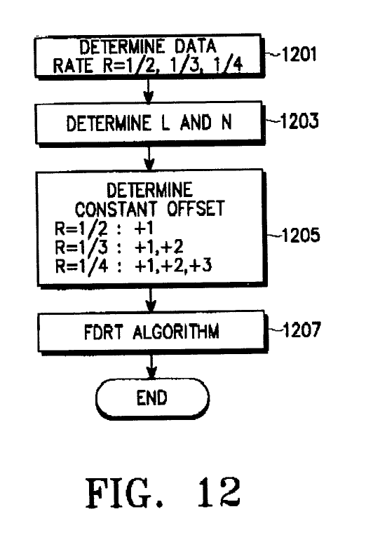

FIG. 12 is another flowchart illustrating an initial offset determining operation to determine the first repeated symbol position in a frame after encoding in an encoder that outputs code symbols in a sequence according to a fourth embodiment of the present invention. Referring to FIG. 12, a code rate is determined in step 1201. The code rate can be 1/2, 1/3, or ¼. In step 1203, the size of an input frame, L and the size of an output frame, N are determined. L is the number of symbols input to an FDRT block or output from an encoder and N is the number of symbols output from the FDRT block. L and N are provided by a higher layer. An offset being a constant is determined according to the determined data rate in step 1205. For example, the offset is given as +1 for R=½,+1 or +2 for R=⅓, and +1, +2, or +3 for R=4. Then, the above-described FDRT algorithm of the present invention is performed in step 1207.

In accordance with the present invention as described above, L code symbols in a frame varying according to a variable data rate are matched to a fixed interleaver size N in a simple structure by controlling an initial offset and thus distributing inserted symbols uniformly within the frame in a data communication system using an error correction code such as a convolutional code, a linear block code, or a turbo code. Consequently, data can be flexibly transmitted according to data rates without performance deterioration.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method of generating a sequence of N symbols from a sequence of L code symbols in a system having an encoder for generating the sequence of L code symbols and a channel interleaver for receiving the sequence of N symbols, N being greater than L, comprising the steps of:
detecting symbols at substantially equidistant (N−L) positions among the L code symbols; and
for each detected symbol, sequentially inserting the detected symbol before or after the position of the detected symbol in the sequence of L code symbols by repetition.

2. The method of claim 1, wherein the code symbols are generated by convolutional encoding.

3. The method of claim 1, wherein the code symbols are generated by linear block encoding.

4. The method of claim 1, wherein the code symbols are generated by turbo encoding.

5. A transmitting device in a communication system, comprising:
an encoder for generating a sequence of L code symbols by encoding source information;
a channel interleaver for receiving a sequence of N symbols being greater than the L code symbols; and
an FDRT (Flexible Data Rate Transmission) block for generating the sequence of N symbols from the sequence of L code symbols by detecting symbols at substantially equidistant (N−L) positions among the L code symbols and for each detected symbol, sequentially inserting the detected symbol before or after the position of the detected symbol in the sequence of L code symbols by repetition.

6. The transmitting device of claim 5, wherein the encoder is a convolutional encoder.

7. The transmitting device of claim 5, wherein the encoder is a linear block encoder.

8. The transmitting device of claim 5, wherein the encoder is a turbo encoder.

9. A method of generating a sequence of N symbols from a sequence of L code symbols being less than the N symbols in a system having a turbo encoder for outputting the L code symbols including a first group of symbols, a second group of symbols, and a third group of symbols and a channel interleaver for receiving the N symbols, the symbols of the first group being of greater significance than the symbols of the second and third groups, the method comprising the steps of:
determining an offset value to select a first repeated symbol position in the second or third group among the L code symbols;
determining symbols at every period starting from the symbol at the position corresponding to the offset value to be non-repeated symbols, the period being determined according to a code rate of the turbo encoder;
detecting substantially equidistant (N−L) symbols among the L code symbols except for the non-repeated symbols; and
for each detected symbol, sequentially inserting the detected symbol before or after the position of the detected symbol in the sequence of L code symbols by repetition.

10. The method of claim 9, wherein when the code rate of the turbo encoder is 1/k, the offset value is a natural number less than k.

11. The method of claim 9, wherein when the code rate of the turbo encoder is 1/k, the period is the product of k and q (q is a natural number).

12. A method of generating a sequence of N symbols from a sequence of L code symbols being less than the N symbols in a communication system having an encoder for generating the sequence of L code symbols and a symbol repeater for repeating (N−L) symbols among the L code symbols to generate the sequence of N symbols, comprising the steps of:
(a) setting an error accumulation value for a first considered symbol of the L code symbols;
(b) comparing the error accumulation value with a predetermined threshold;
(c) repeating a symbol corresponding to the considered symbol if the error accumulation value is less than the threshold and resetting a new error accumulation value for the corresponding symbol by adding the error accumulation value to a predetermined increment and returning to step (b);
(d) setting a new error accumulation value obtained by subtracting a predetermined decrement from the error accumulation value for a next symbol if the error accumulation value is greater than the threshold and returning to step (b); and
(e) ending the steps if the sequence of N symbols are generated from the L code symbols during the step (c) or (d).

13. The method of claim 12, wherein the step (a) comprises the steps of
(a1) calculating a first parameter by multiplying a second variable Ib by L, a first variable Ia and the second variable Ib being used to determine the first repeated symbol position in a predetermined frame and the second variable Ib being an integer satisfying 1≦Ib≦Ia;
(a2) calculating a second parameter by multiplying the first variable by (N−L); and
(a3) setting the error accumulation value for the first symbol among the L code symbols by subtracting the second parameter from the first parameter.

14. The method of claim 12, wherein the threshold is 0.

15. The method of claim 13, wherein the increment is the product of the first variable and L.

16. The method of claim 13, wherein the decrement is the first parameter.

17. An apparatus for generating a sequence of N symbols from a sequence of L code symbols being less than the N symbols in a communication system having an encoder for generating the sequence of L code symbols and a symbol repeater for repeating (N−L) symbols among the L code symbols to generate the sequence of N symbols, the apparatus comprising:
a register for outputting a first parameter being the product of a second variable Ib and L as a first error accumulation value, a first variable Ia and the second variable Ib being used to determine the first repeated symbol position in a predetermined frame and the second variable Ib being an integer satisfying 1≦Ib≦Ia;
a subtractor for subtracting a second parameter being the product of the first variable and (N−L) from the first error accumulation value and outputting the subtraction result as a second error accumulation value;
a selector for receiving the second error accumulation value and a third accumulation value and outputting the second or third error accumulation value selectively as a fourth error accumulation value;
an adder for receiving the fourth error accumulation value, adding the fourth error accumulation value to a third parameter being the product of the first variable and L, and outputting the sum as the third error accumulation value;
a comparator for comparing the fourth error accumulation value with a predetermined threshold and generating an output signal according to a result of the comparing; and
a symbol repeater for receiving at least one output signal from the comparator for each symbol and repeating a symbols for which an output signal is from the result that the error accumulation value is less than or equal to the threshold, thereby generating the sequence of N symbols,
wherein the comparator outputs a control signal to control the selector to select the second error accumulation value as the fourth error accumulation value if the fourth error accumulation value is greater than the threshold and outputs a control signal to control the selector to select the third error accumulation value as the fourth error accumulation value if the fourth error accumulation value is less than or equal to the threshold; and
the register outputs the first parameter as the first error accumulation value for the first symbol among the L code symbols and the second error accumulation values of the previous symbols as updated first error accumulation values for the following symbols.

18. The apparatus of claim 17, further comprising an inverter connected between the comparator and the register, for enabling the register in response to a control signal from the comparator to update the first error accumulation value with the second error accumulation value.

19. The apparatus of claim 18, wherein the register is enabled in response to the control signal if the comparator determines that the fourth error accumulation value is greater than the threshold, updates the first error accumulation value with the second error accumulation value, and outputs the updated first error accumulation value.

20. The apparatus of claim 17, wherein the threshold is 0.
